(19) United States
(12) Patent Application Publication
(10) Pub. No.: US 2010/0065249 A1
(43) Pub. Date: Mar. 18, 2010

(54) HEAT SINK

(75) Inventor: Jin Hsun Liu, Sinjhuang City (TW)

Correspondence Address: NIKOLAI & MERSEREAU, P.A., 900 SECOND AVENUE SOUTH, SUITE 820, MINNEAPOLIS, MN, 55402, US

(73) Assignee: Asia Vital Components Co., Ltd., Sinjhuang City (TW)

(21) Appl. No.: 12/212,082

(22) Filed: Sep. 17, 2008

(51) Int. Cl. H05K 7/20

(52) U.S. Cl. 165/80.3; 361/702

(57) ABSTRACT

A heat sink includes a radiating base being provided on one face with perpendicularly extended radiating fins, and on another opposite face with a protruded seat. Two opposite lateral sides of the radiating base are outward extended, from two upper longitudinal edges of the protruded seat. A first space is formed between any two adjacent ones of the radiating fins, and at least one through hole is formed on the radiating base to communicate the first spaces with spaces formed below the radiating base at two outer sides the protruded seat. The heat sink is mounted to a heat-producing element. Ambient cold air can flow downward and enter the spaces below the radiating base, and then flow upward through the at least one through hole into the first spaces to carry away heat transferred to the radiating fins and thereby upgrade the heat dissipation efficiency of the heat sink.

### FIELD OF THE INVENTION

The present invention relates to a heat sink, and more particularly to a heat sink for use in an electronic device.

### BACKGROUND OF THE INVENTION

Due to the progress in semiconductor technique, the volume of integrated circuit (IC) has become smaller and smaller. Electronic elements for IC, such as a central processing unit, would produce more heat per unit time when the operating speed thereof is increased. The produced heat must be timely discharged to avoid rising of temperature and unstable operation. In general, a heat sink is mounted to the central processing unit to increase heat-radiating area and upgrade heat-dissipating efficiency, so as to lower the temperature of the central processing unit and the south and north bridge chips.

FIGS. 1a and 1b are assembled perspective and side views, respectively, of a conventional heat sink 1. As shown, the heat sink 1 includes a radiating base 11 having an upper face 111 and a lower face 112. A plurality of radiating columns 1111 or radiating fins is formed on the upper face 111 of the radiating base 11. The lower face 112 of the radiating base 11 is a flat face for contacting with a heat-producing source 2, so that heat produced by the heat-producing source 2 is transferred to the whole heat sink 1 via the radiating base 11. The heat transferred to the heat sink 1 is then radiated from the radiating columns 1111 and dissipated into ambient air. The heat sink 1 with the above-described arrangements has very low heat dissipating efficiency. Moreover, the heat-producing source 2 has a small thickness and the heat sink 1 is immediately mounted to a top of the heat-producing source 2. As a result, there is only a very narrow space 13 around the heat-producing source 2. The narrow space 13 prevents heat 21 produced by the heat-producing source 2 from smoothly diffusing upward or sideward, bringing the heat 21 to stagnate around the heat-producing source 2. On the other hand, the narrow space 13 also prevents cold air 3 near the heat sink 1 from flowing toward the heat-producing source 2 to carry away the heat 21 produced by the heat-producing source 2. Meanwhile, air-carrying heat is also uneasy to flow out of the narrow space 13 and tends to stagnate therein to cause constant temperature rising of the heat-producing source 2. This condition would largely lower the heat dissipating efficiency of the heat-producing source 2 and even lead to burnout of the chips in the heat-producing source 2.

In brief, the conventional heat sink 1 has the following disadvantages: (1) having low heat-dissipating effect; (2) easy to cause stagnant hot air around the heat-producing source; (3) not allowing heat produced by the heat-producing source to diffuse efficiently; (4) providing poor heat exchange efficiency; and (5); failing to enable natural air convection near the heat-producing source.

It is therefore tried by the inventor to develop an improved heat sink to overcome the drawbacks of the conventional heat sink.

### SUMMARY OF THE INVENTION

A primary object of the present invention is to provide a heat sink, which allows natural convection of ambient hot and cold fluid or air to thereby provide upgraded heat dissipating effect.

To achieve the above and other objects, the heat sink according to the present invention includes a radiating base, a plurality of radiating fins, and a protruded seat. The radiating fins are perpendicularly extended from one face of the radiating base. The protruded seat is protruded from another opposite face of the radiating base. Two lateral sides of the radiating base are extended from two outer sides of the protruded seat, so that two spaces are formed below the radiating base at the two outer sides of the protruded seat. A first space is formed between any two adjacent ones of the radiating fins. The radiating base is formed with at least one through hole communicating the first space with the spaces below the radiating base at two outer sides of the protruded seat. The radiating fins are correspondingly formed with at least one notch, so that the notches correspondingly formed on the radiating fins together form at least one channel communicating with the first spaces. The heat sink is mounted to a heat-producing element, so that heat produced by the heat-producing element is conducted to the heat sink. Cold fluid or air above or around the heat sink can flow downward to the heat-producing element via the spaces below the radiating base at two outer sides of the protruded seat, and then upward flow through the at least one through hole into the first spaces to cool the radiating fins. Meanwhile, hot fluid or air formed under the radiating base and around the heat-producing element can freely flow upward through the through hole into the first spaces to diffuse upward and outward as the result of natural air convection. Therefore, the heat-dissipating effect of the heat sink can be largely upgraded.

With the above arrangements, the beat sink of the present invent ion has the following advantages: (1) having good heat dissipating efficiency; (2) preventing heat produced by the heat-producing element from stagnating therearound; (3) enabling good heat exchange, efficiency; (4) providing increased heat-dissipating area arid space; (5) allowing heat to dissipate in different directions; and (6) enabling the occurrence of natural air convection.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1a is a perspective view showing the mounting of a conventional heat sink to a top of a heat-producing element;

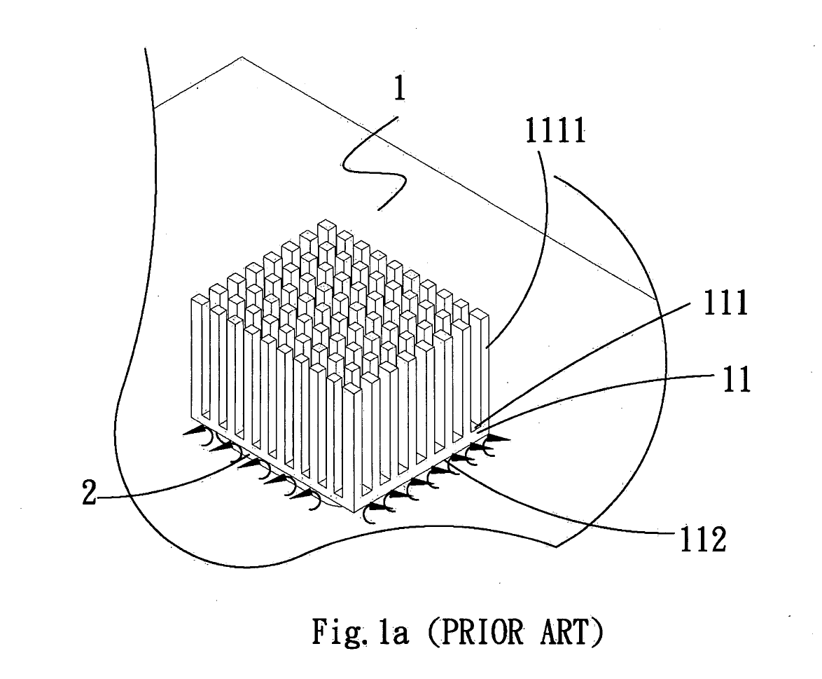

FIG. 1b is a side view of FIG. 1a;

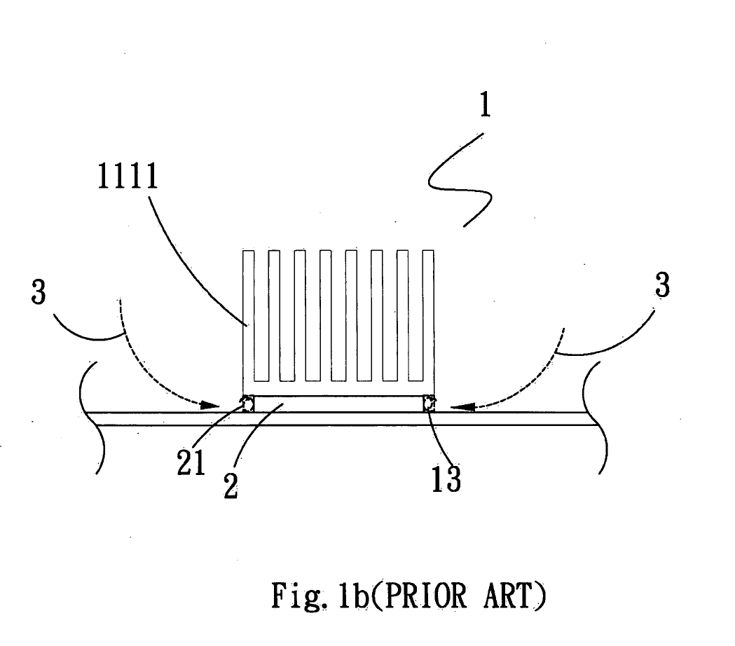

FIG. 2 is an exploded perspective view of a heat sink according to a first embodiment of the present invention before being mounted to a heat-producing element;

FIG. 3 is an assembled view of FIG. 2;

FIG. 4a is an assembled perspective view showing the heat sink of FIG. 3 in use;

FIG. 4b is a side view of FIG. 4a;

FIG. 5a is an exploded perspective view of a heat sink according to a second embodiment of the present invention;

FIG. 5b is an assembled view of FIG. 5a; and

FIG. 6 is a front view of a heat pipe for the heat sink of FIGS. 5a and 5b.

### DETAILED DESCRIPTION OF THE PREFERRED EMBODIMENTS

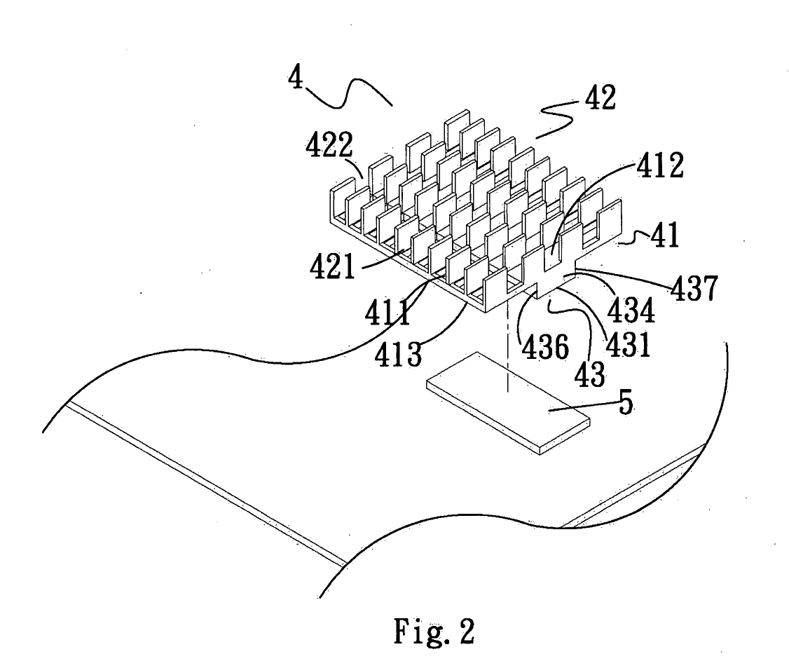

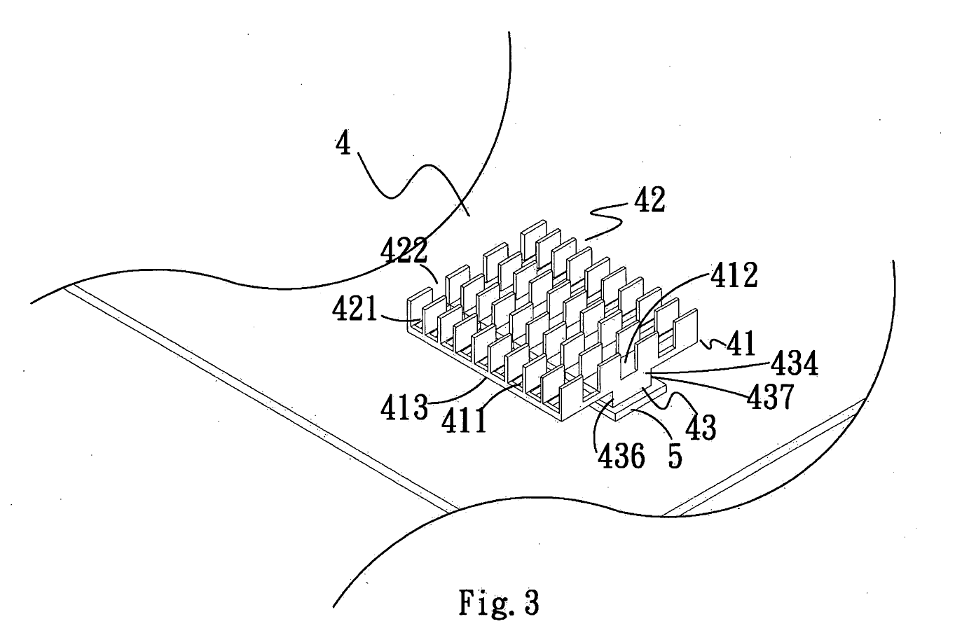

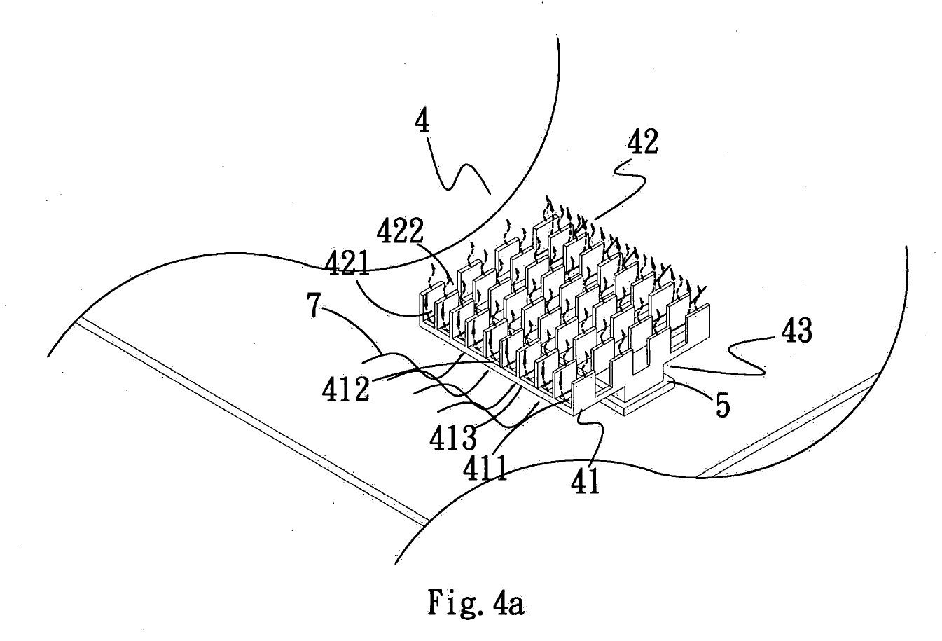

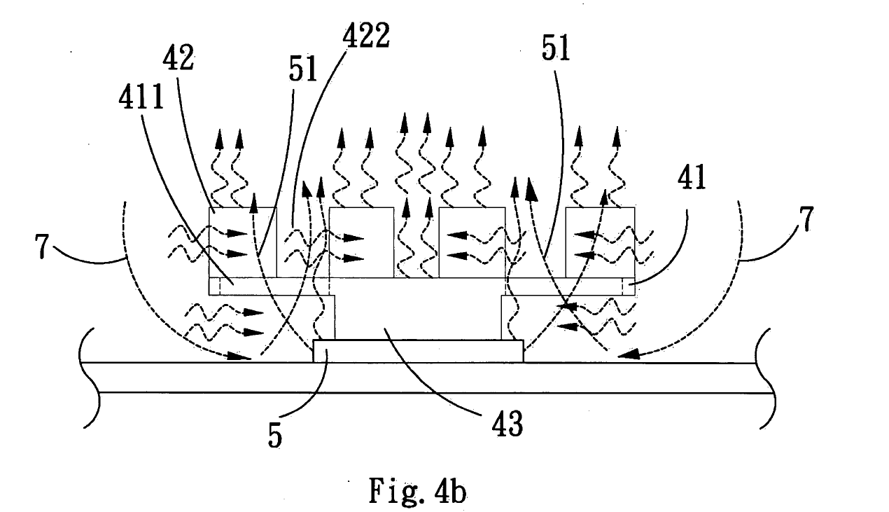

Please refer to FIGS. 2 and 3 that are exploded and assembled perspective views, respectively, showing a heat sink 4 according to a first embodiment of the present invention before and after being mounted to a heat-producing element 5; and to FIGS. 4a and 4b that are perspective and side views, respectively, showing the heat sink 4 in use. As shown, the heat sink 4 includes a radiating base 41, a plurality of radiating fins 42, and a protruded seat 43. The radiating fins 42 are upward and perpendicularly extended from an upper face 412 of the radiating base 41. The protruded seat 43 is downward protruded from a lower face 413 of the radiating base 41, such that the radiating base 41 has two opposite lateral sides outward extended from two upper longitudinal edges of the protruded seat 43 by a predetermined distance each to thereby define two spaces below the radiating base 41 at two outer sides of the protruded seat 43. A first space 421 is formed between any two adjacent ones of the radiating fins 42.

At least one through hole 411 is formed on the radiating base 41 to communicate the first spaces 421 with the spaces below the radiating base 41.

The radiating fins 42 are correspondingly formed with at least one notch, so that the notches correspondingly formed on the radiating fins 42 together form a channel 422 extended in a direction perpendicular to the radiating fins 42 and communicating with the first spaces 421, the at least one through hole 411, and the spaces below the two opposite lateral sides of the radiating base 41.

The protruded seat 43 is downward protruded from the lower face 413 of the radiating base 41. A bottom face of the protruded seat 43 can contact with at least one heat-producing element 5 to conduct heat produced by the heat-producing element 5 to the whole heat sink 4.

The radiating fins 42 are upward protruded from the upper face 412 of the radiating base 41, and are arranged in parallel to each other.

The first spaces 421 formed between adjacent radiating fins 42 intersect and communicate with the at least one channel 422 formed by the notches correspondingly formed on the radiating fins 42. The at least one through hole 411 can be formed on the radiating base 41 at a position corresponding to the first spaces 421 and/or the at least one channel 422 to communicate with the spaces below the two opposite lateral sides of the radiating base 41.

The heat sink 4 is mounted on the heat-producing element 5 with the bottom face 431 of the protruded seat 43 in direct contact with the heat-producing element 5, so that heat produced by the heat-producing element 5 is transferred via the protruded seat 43 to the radiating fins 42, and then radiated from the radiating fins 42 to diffuse in ambient air. Meanwhile, hot fluid or air 51 formed around the heat-producing element 5 can flow upward through the at least one through hole 411 into the first spaces 421 and the at least one channel 422 to dissipate into ambient environment. Accordingly, the heat sink 4 of the present invention enables upgraded heat dissipation efficiency, and the hot fluid or air 51 would not stagnate around the heat-producing element 5.

Moreover, cold fluid or air 7 above or around the heat sink 4 can flow downward to the heat-producing element 5 via the spaces formed below the radiating base 41 at two outer sides of the protruded seat 43, and then flow upward through the at least one through hole 411 into the first spaces 421 and the channels 422 to carry away the heat radiated from the heat sink 4 and the heat produced by the heat-producing element 5. The cold fluid or air 7 can very smoothly flow within the first spaces 421 and the channels 422 to speed the upward and outward diffusion of the hot fluid or air 51. That is, the heat sink 4 allows natural circulation of surrounding hot and cold fluid or air to thereby obtain a largely upgraded heat-dissipating efficiency.

The heat sink 4 can be integrally formed to reduce the occurrence of thermal resistance.

Furthermore, the hot fluid or air 51 diffused from the heat-producing element 5 can also flow through the at least one through hole 411 into the first spaces 421 and the channels 422 to freely dissipate upward and outward.

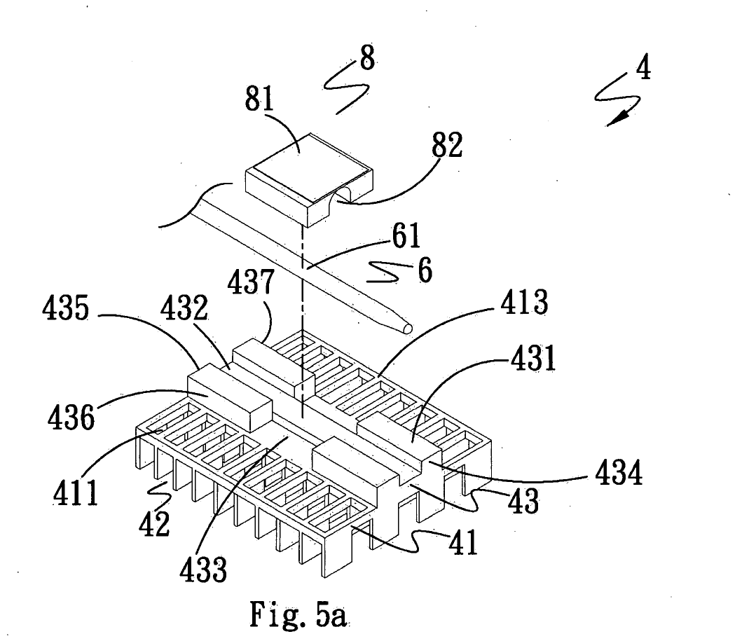

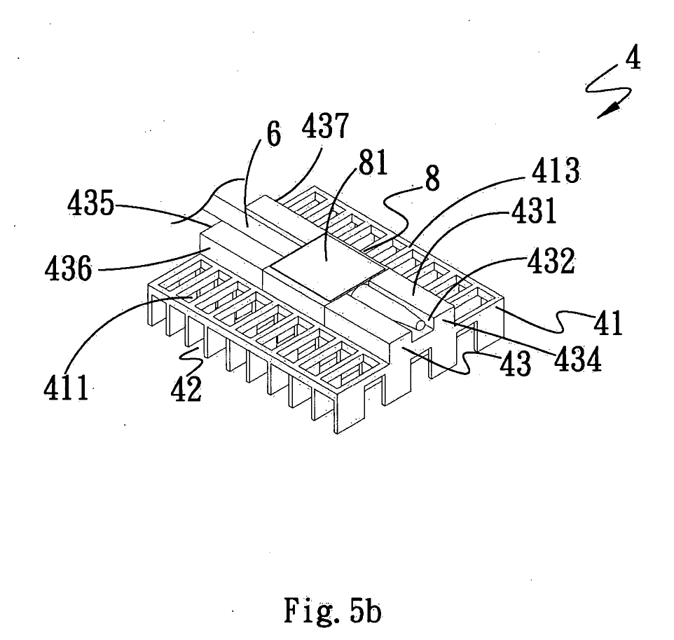

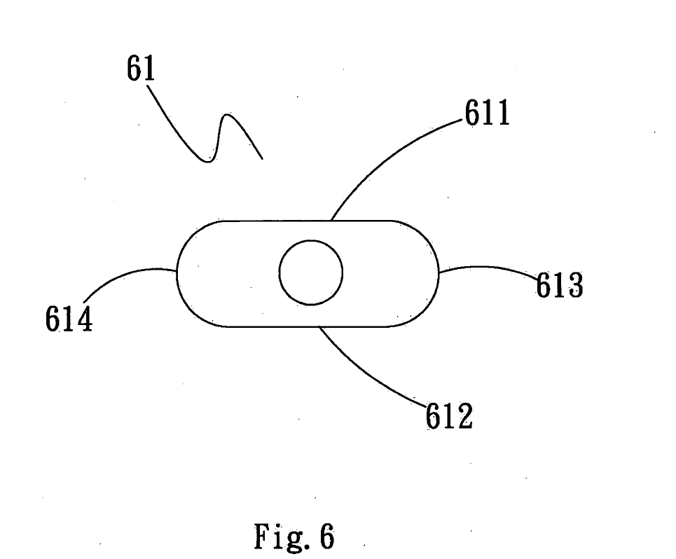

Please reefer to FIGS. 5a and 5b that are exploded and assembled perspective views, respectively, of a heat sink 4 according to a second embodiment of the present invention, and to FIG. 6 that is a front view of a heat pipe for the heat sink 4 of the second embodiment. The heat sink 4 in the second embodiment is different from that in the first embodiment in that the bottom face 431 of the protruded seat 43 is formed with at least one guide channel 432 longitudinally extended from a front end 434 of the protruded seat 43 to a rear end 435 thereof, and a recess 433 transversely extended from a first longitudinal side 436 of the protruded seat 43 to a second longitudinal side 437 thereof, such that the guide channel 432 and the recess 433 perpendicularly intersect and communicate with each other.

A heat conduction end 61 of a heat pipe 6 is snugly received in the guide channel 432. In addition, a bottom plate 8 is snugly fitted in the recess 433. The bottom plate 8 has a first face serving as a contact face 81 for contacting with the at least one heat-producing element 5, and a second face opposite to the contact face 81 and formed with a longitudinally extended groove 82 for snugly receiving the heat pipe 6 therein. Therefore, when the bottom plate 8 is fitted in the recess 433, the heat pipe 6 is fixedly held between the guide channel 432 of the protruded seat 43 and the groove 82 of the bottom plate 8.

Referring to FIG. 6, which is a front view of the heat pipe 6, the heat conduction end 61 has two opposite contact faces 611, 612 and two opposite lateral faces 613, 614 extended from the contact faces 611, 612. One of the contact faces 611, 612 is bearing on an inner wall surface of the guide channel 432, while the other one of the contact faces 611, 612 is bearing on an inner wall surface of the groove 82 of the bottom plate 8. The inner wall surface of the groove 82 fixedly presses the heat pipe 6 against the heat sink 4. With the heat pipe 6, the heat produced by the heat-producing element 5 can be more quickly transferred to the heat sink 4 to thereby upgrade the heat-dissipation efficiency of the heat sink 4.

A heat-conducting bonding agent, such as tin paste, can be further applied between the heat conduction end 61 of the heat pipe 6 and the inner wall surfaces of the guide channel 432 and the groove 82, so as to firmly bond the heat pipe 6 to the heat sink 4.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat sink, comprising a radiating base, a plurality of radiating fins perpendicularly extended from an upper face of the radiating base, and a protruded seat protruded from a lower face of the radiating base; two opposite lateral sides of the radiating base being outward extended from two upper longitudinal edges of the protruded seat to define two spaces below the radiating base at two outer sides of the protruded seat; a first space being formed between any two adjacent ones of the radiating fins; at least one through hole being formed on the radiating base to communicate the first spaces with the spaces below the radiating base at two outer sides the protruded seat; whereby ambient cold fluid or air can flow downward and enter the spaces formed below the radiating base at two outer sides of the protruded seat, and then upward flow through the at least one through hole into the first spaces to carry away heat transferred to the radiating fins.

2. The heat sink as claimed in claim 1, wherein the radiating fins are correspondingly formed with at least one notch, so that the notches correspondingly formed on the radiating fins together form at least one channel communicating with the first spaces.

3. The heat sink as claimed in claim 2, wherein the at least one channel is extended in a direction perpendicular to the radiating fins and has a depth reaching the upper face of the radiating base.

4. The heat sink as claimed in claim 1, wherein the at least one through hole communicates with the at least one channel.

5. The heat sink as claimed in claim 1, wherein the radiating base and the radiating fins are integrally formed.

6. The heat sink as claimed in claim 1, wherein the radiating base and the protruded seat are integrally formed.

7. The heat sink as claimed in claim 1, wherein the protruded seat is formed at a bottom face thereof with a recess, in which a bottom plate is snugly fitted; and the bottom plate having a contact face for contacting with at least one heat-producing element, and a groove formed on another face opposite to the contact face for receiving a heat pipe therein.

8. The heat sink as claimed in claim 6, wherein the protruded seat is formed at a bottom face thereof with a recess, in which a bottom plate is snugly fitted; and the bottom plate having a contact face for contacting with at least one heat-producing element, and a groove formed on another face opposite to the contact face for receiving a heat pipe therein.

9. The heat sink as claimed in claim 7, wherein a heat-conducting bonding agent is applied between the heat pipe and the groove and the bottom plate.

10. The heat sink as claimed in claim 8, wherein a heat-conducting bonding agent is applied between the heat pipe and the groove and the bottom plate.
